(19) United States
(12) Patent Application Publication
(10) Pub. No.: US 2026/0255648 A1
(43) Pub. Date: Aug. 27, 2026

(54) BACKSIDE OFFSET GATE CONTACT FOR BACKSIDE SPACING

(71) Applicant: INTERNATIONAL BUSINESS MACHINES CORPORATION, ARMONK, NY (US)

(72) Inventors: Xiaoming Yang, Clifton Park, NY (US); Reinaldo Vega, Mahopac, NY (US); Ruilong Xie, Niskayuna, NY (US); Kisik Choi, Watervliet, NY (US); Ravikumar Ramachandran, Pleasantville, NY (US); Tao Li, Slingerlands, NY (US)

(21) Appl. No.: 19/063,728

(22) Filed: Feb. 26, 2025

(51) Int. Cl. H10D 64/23; H10D 30/00; H10D 30/01; H10D 30/43; H10D 62/10; H10D 84/01; H10D 84/83

(52) U.S. Cl. CPC H10D 64/251; H10D 30/014; H10D 30/0191; H10D 30/43; H10D 30/502; H10D 62/121; H10D 84/0149; H10D 84/832

(57) ABSTRACT

Embodiments disclosed herein include a semiconductor structure. The semiconductor structure may include a first source/drain (S/D) electrically connected to a backside contact on a backside. A device may include a second S/D electrically connected to a frontside contact on a frontside. A device may include a channel comprising a bottom dielectric isolation (BDI) between the first S/D and the second S/D. A device may include a backside interlayer dielectric (BILD) protruding past the BDI into direct contact with the second S/D. A device may include a residual silicon between the BILD and the backside contact.

### BACKGROUND

The present invention relates generally to the field of manufacturing semiconductor structures, and more particularly to removing silicon without damaging source/drains.

Direct Bonded Copper (DBC) involves bonding a copper layer directly to a ceramic substrate (e.g., alumina or silicon nitride) of a semiconductor structure, for example using a high-temperature oxidation process. The resulting DBC substrate offers excellent thermal conductivity, electrical insulation, and mechanical stability, which provides power electronics applications with efficient heat dissipation and reliable performance. Silicon present in the semiconductor structure can significantly impact DBC due to thermal expansion mismatch between silicon and the ceramic substrates. This mismatch can result in stress and potential delamination during thermal cycling. Additionally, bonding silicon chips to DBC substrates requires precise control over bonding parameters to ensure strong adhesion without damaging the silicon. Therefore, careful material selection and process optimization are crucial when integrating silicon with DBC technology, and removal of silicon within the semiconductor structure can decrease the potential for defects.

In some aspects, the techniques described herein relate to a semiconductor structure, including: a first source/drain (S/D) electrically connected to a backside contact on a backside; a second S/D electrically connected to a frontside contact on a frontside; a channel including a bottom dielectric isolation (BDI) between the first S/D and the second S/D; a backside interlayer dielectric (BILD) protruding passed the BDI into the second S/D; and a residual silicon between the BILD and the backside contact.

In some aspects, the techniques described herein relate to a method, including: forming a front-end-of-line (FEOL) in silicon including a first gate including a bottom dielectric isolation (BDI), a first source/drain (S/D) that protrudes below the BDI, and a second S/D that protrudes below the BDI; and etching the silicon and a portion of the second S/D to form a void; and depositing a backside interlayer dielectric (BILD) that protrudes into the second S/D passed the BDI.

In some aspects, the techniques described herein relate to a semiconductor structure, including: a first source/drain (S/D) electrically connected to a backside contact on a backside; a second S/D adjacent to the first S/D; a backside interlayer dielectric (BILD) on the backside of the second S/D; and a residual silicon between the BILD and the backside contact.

### BRIEF DESCRIPTION OF THE DRAWINGS

FIG. 1 depicts a schematic top view depicting a semiconductor structure, in accordance with one embodiment of the present invention.

FIGS. 2A and 2B depict cross-sectional side views of a front-end-of-line (FEOL) of the semiconductor structure, in accordance with one embodiment of the present invention.

FIGS. 3A and 3B depict cross-sectional side views of a FEOL of the semiconductor structure, in accordance with one embodiment of the present invention.

FIGS. 4A and 4B depict cross-sectional side views of the semiconductor structure, in accordance with one embodiment of the present invention.

FIGS. 5A and 5B depict cross-sectional side views of the semiconductor structure, in accordance with one embodiment of the present invention.

FIGS. 6A and 6B depict cross-sectional side views of the semiconductor structure, in accordance with one embodiment of the present invention.

FIG. 6C depicts a cross-sectional side view of the semiconductor structure along a line that is not shown in FIG. 1.

FIG. 6D depicts a cross-sectional side view of a semiconductor structure along an extended line A-A' in FIG. 1.

FIGS. 7A and 7B depict cross-sectional side views of the semiconductor structure, in accordance with one embodiment of the present invention.

FIGS. 8A and 8B depict cross-sectional side views of the semiconductor structure, in accordance with one embodiment of the present invention.

FIGS. 9A and 9B depict cross-sectional side views of the semiconductor structure, in accordance with one embodiment of the present invention.

FIGS. 10A and 10B depict cross-sectional side views of a semiconductor structure, in accordance with one embodiment of the present invention.

FIGS. 11A and 11B depict cross-sectional side views of a semiconductor structure, in accordance with one embodiment of the present invention.

FIGS. 12A and 12B depict cross-sectional side views of the semiconductor structure of FIGS. 11A and 11B, in accordance with one embodiment of the present invention.

FIGS. 13A and 13B depict cross-sectional side views of the semiconductor structure of FIGS. 11A and 11B, in accordance with one embodiment of the present invention.

FIGS. 14A and 14B depict cross-sectional side views of a semiconductor structure, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

As mentioned above, the presence of silicon in semiconductor structures that use DBC processes can result in defects. Removing silicon, however, poses significant challenges due to the difficulty in achieving high selectivity between silicon and other materials, such as dielectrics. The etch rate for silicon must be meticulously controlled to ensure precision and avoid over-etching into, for example, source/drains (S/Ds) in the device level of the semiconductor structure. Any variation in depth of etching the S/Ds can cause inconsistencies in device dimensions, leading to defects in the final semiconductor structure. When the etch depth is not uniform, critical device features may not be accurately formed, affecting the electrical performance and functionality of the semiconductor devices. As a result, a higher number of devices may fail to meet the required specifications, reducing the overall yield. Additionally, tight control over etch depth variation is essential to ensure that the majority of devices on a wafer perform consistently, thus maximizing the number of usable devices. Therefore, minimizing silicon etch depth variation is crucial for achieving high manufacturing yield and reducing production costs.

The embodiments described below, therefore, include semiconductor structures that replace silicon with a backside interlayer dielectric (BILD) through a process that increases the etch depth variation margin by forming a bottom dielectric isolation (BDI) in the gate region, and forming S/Ds that protrude below the BDI. The final structure may thus include a protrusion of the S/Ds in the location where the S/D contacts a backside contact.

The present invention and an example fabrication process will now be described in detail with reference to the Figures.

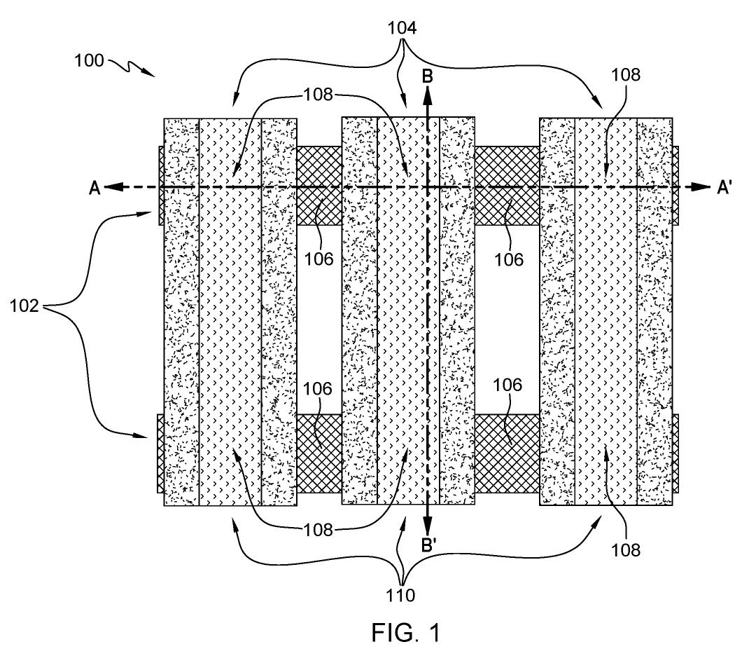

FIG. 1 depicts a schematic top view depicting a semiconductor structure 100, in accordance with one embodiment of the present invention. The illustrated stage of the semiconductor structure 100 includes rows 102 and columns 104. The two rows 102 represent limited examples of a circuit that may include many hundreds or thousands of rows. The semiconductor structure 100 may also include gates 108 organized in the columns 104 that cross the rows 102 between source/drains (S/Ds) 106 to form individual field-effect transistors (FETs) 110 and control signal flow along the rows 102. The FETs 110, once formed, are electrically connected to power and signal networks through S/D contacts (not illustrated in FIG. 1) that are etched and metalized as part of the fabrication of the semiconductor structure 100. The dimensions of the FETs are small, such that tiny misalignment or over/under etching of the contacts can result in shorting and defects. To reduce the likelihood of defects caused by shorting, the embodiments disclosed below include S/Ds that protrude below a bottom dielectric isolation to contact a backside contact, and a bottom interlayer dielectric. Example processes are illustrated in the stages described below.

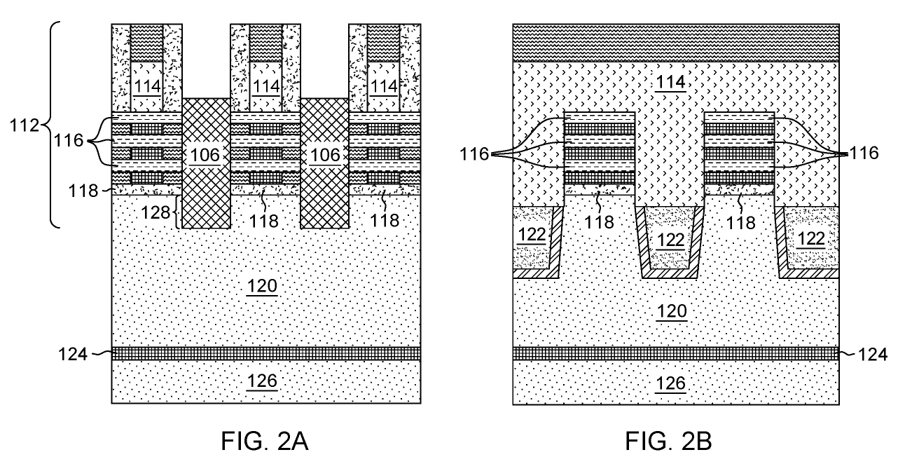

FIGS. 2A and 2B depict cross-sectional side views of a front-end-of-line (FEOL) 112 of the semiconductor structure 100, in accordance with one embodiment of the present invention. FIG. 2A is a cross-sectional view along line A-A’ in FIG. 1, and FIG. 2B is a cross-sectional view along line B-B’ in FIG. 1. The FEOL 112 includes the S/Ds 106, formed between dummy gates 114 masking a pattern of nanosheet channels 116. The nanosheet channels 116 are initially formed as blanket layers with sacrificial layers between, and a bottom dielectric isolation (BDI) 118 at the bottom that isolates the nanosheet channels 116 from a substrate of silicon 120. After the blanket layers are formed, a directional etch process may be used to etch trenches for the S/Ds 106, after which the sacrificial layers may be recessed to make room for spacers that are also between the nanosheet channels 116. The nanosheet channels 116 are also etched along the rows 102, with a shallow trench isolation (STI) 122 formed between the nanosheet channels 116 as shown in FIG. 2B. In addition to the silicon 120, the substrate also includes an etch stop layer 124 and a carrier substrate 126, utility of which will be demonstrated in the description below. The S/Ds 106 are epitaxially grown in the trenches and protrude a protrusion depth 128 into the silicon 120 passed the BDI 118. The protrusion depth 128 may be determined by extending the amount of time taken to etch through blanket layers that form the nanosheet channels 116.

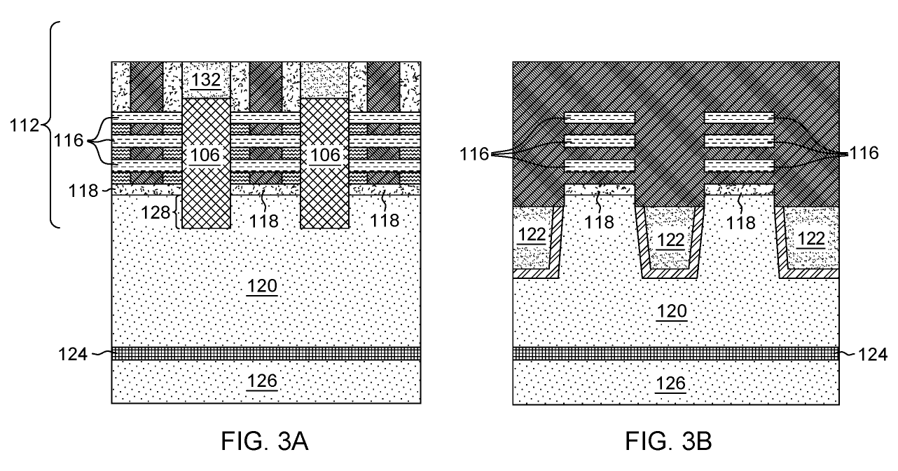

FIGS. 3A and 3B depict cross-sectional side views of a FEOL 112 of the semiconductor structure 100, in accordance with one embodiment of the present invention. FIG. 3A is a cross-sectional view along line A-A’ in FIG. 1, and FIG. 3B is a cross- sectional view along line B-B’ in FIG. 1. The semiconductor structure 100 now includes a high-κ metal gate (HKMG) 130. The HKMG 130 replaces the dummy gates 114 and is insulated from the S/Ds 106 by the inner spacers, and from the silicon 120 by the BDI 118. The semiconductor structure 100 also includes an interlayer dielectric (ILD) 132 covering the S/Ds 106. The semiconductor structure 100 may be subjected to chemical-mechanical polishing (CMP) after the HKMG 130 and the ILD 132 are deposited, to prepare the semiconductor structure 100 for the next stages in fabrication.

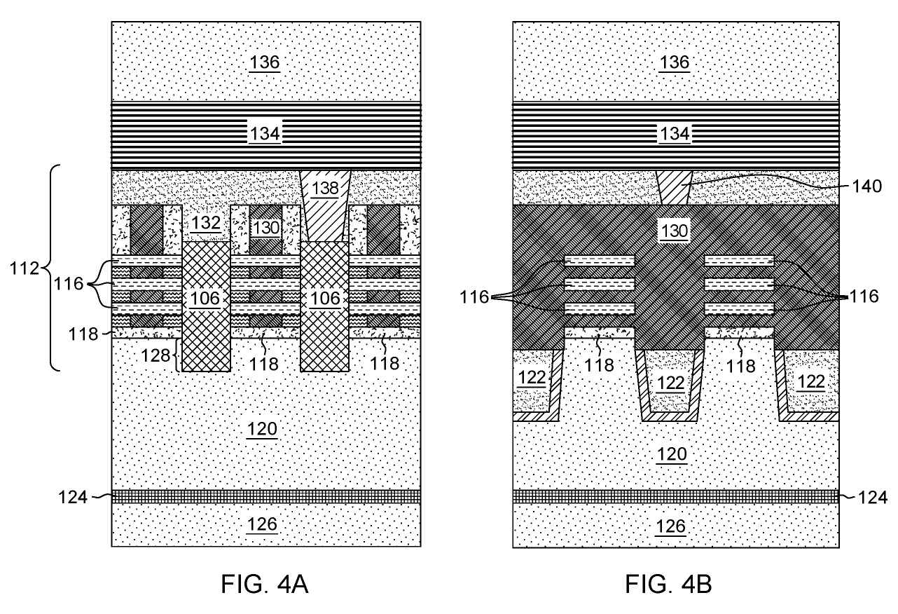

FIGS. 4A and 4B depict cross-sectional side views of the semiconductor structure 100, in accordance with one embodiment of the present invention. FIG. 4A is a cross-sectional view along line A-A’ in FIG. 1, and FIG. 4B is a cross- sectional view along line B-B’ in FIG. 1. The semiconductor structure 100 now includes a back-end of line (BEOL) 134 and a carrier wafer 136 both connected to a frontside of the semiconductor structure 100. The BEOL 134 is not shown to scale, and may include many layers of interconnects, wires, and metal connective pathways, each layer of which may be many times larger and thicker than the FEOL 112. The carrier wafer 136 may also be thicker and more substantial than the FEOL 112, and is used as a structural support for the semiconductor structure 100 during many of the fabrication steps below. The BEOL 134 is electrically connected to the FEOL 112 by S/D contacts 138. The S/D contacts 138 are formed as an initial step, before the rest of the BEOL 134 is formed, and are fabricated by applying a mask, lithographically patterning the mask, then etching a hole and filling the hole with the conductive material of the S/D contact 138. Gate contacts 140 are formed in a similar manner, and may be metalized in the same step as the S/D contacts 138.

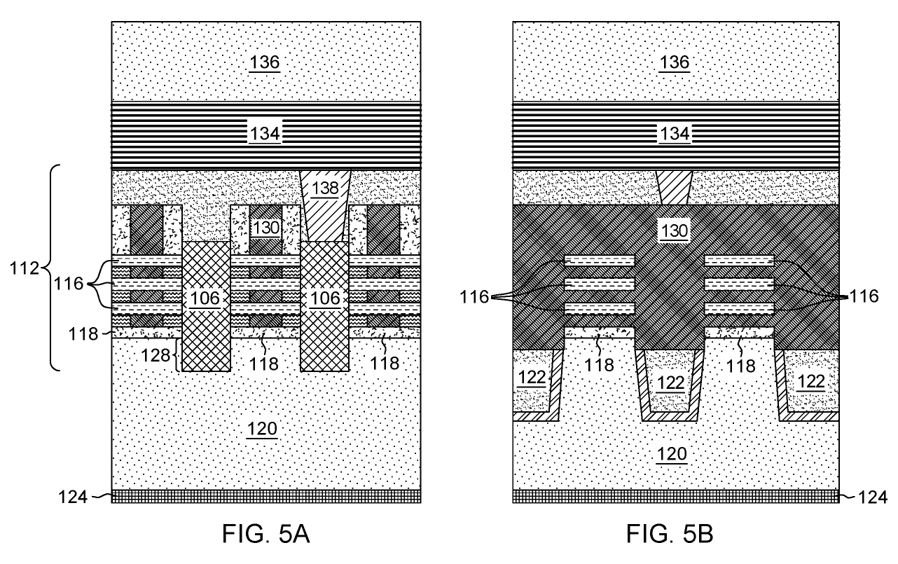

FIGS. 5A and 5B depict cross-sectional side views of the semiconductor structure 100, in accordance with one embodiment of the present invention. FIG. 5A is a cross-sectional view along line A-A’ in FIG. 1, and FIG. 5B is a cross- sectional view along line B-B’ in FIG. 1. The semiconductor structure 100 now has the carrier substrate 126 removed. To facilitate this etching, the semiconductor structure 100 is flipped. For consistency in explanation and orientation of a typical use-case of the semiconductor structure 100, the figures will keep the BEOL 134 at the top, even when processes at one stage or another are performed at a different orientation. The semiconductor structure 100 uses the etch stop layer 124 to enable a rough etch process which removes the carrier substrate 126 quickly. The etch stop layer 124 is monitored (e.g., electrical potential, vibrational monitoring) so that the rough etch process can be cut off before accidentally etching other unintended components. Example materials of the etch stop layer 124 can be a SiGe or SiO₂.

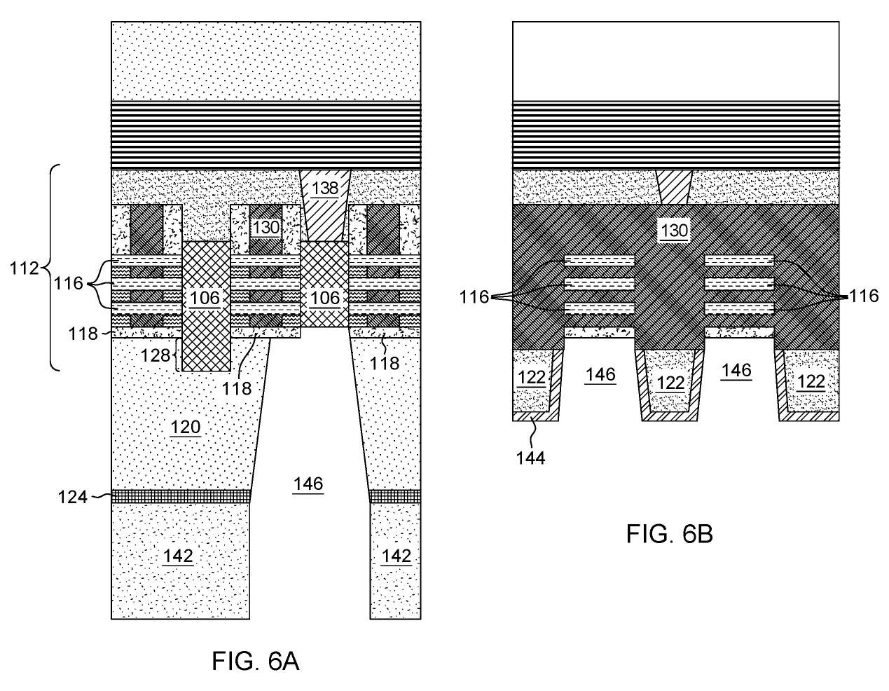

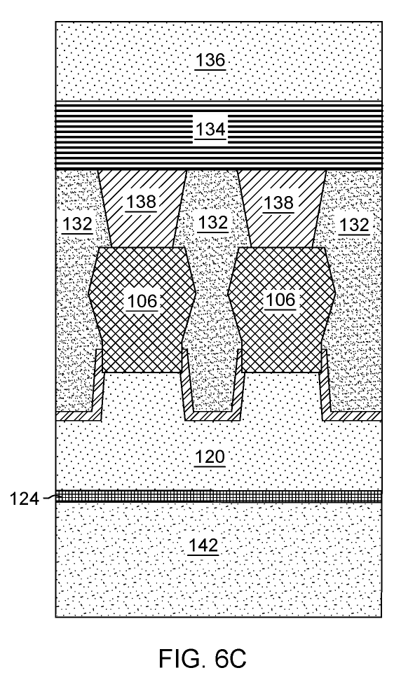

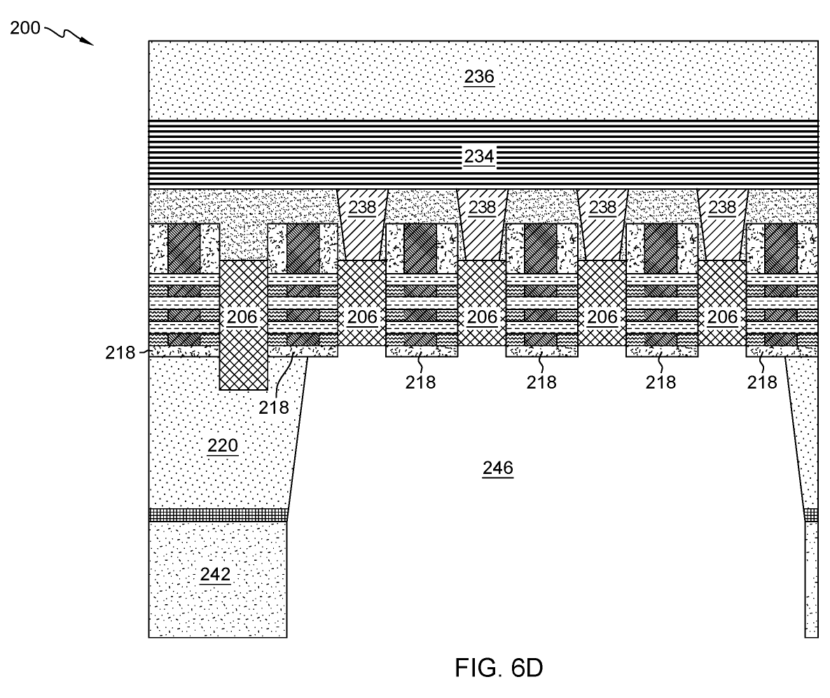

FIGS. 6A and 6B depict cross-sectional side views of the semiconductor structure 100, in accordance with one embodiment of the present invention. FIG. 6A is a cross-sectional view along line A-A’ in FIG. 1, and FIG. 6B is a cross- sectional view along line B-B’ in FIG. 1. The semiconductor structure 100 now includes a patterning mask, such as an organic planarization layer (OPL) 142 that has been patterned to cover certain S/Ds 106 while exposing the area above (below in the drawing) other S/Ds 106. The protected S/D contacts 106 are shielded by the OPL 142 from a selective etch process that removes the silicon 120 and potentially the unprotected S/Ds 106. The etch process used to remove the silicon 120 is selective against etching the BDI 118 and the HKMG 130. The inclusion of the BDI 118 increases the silicon etch depth variation margin, making it safer to etch the silicon 120 without damaging the HKMG 130. The STI 122 may also include an oxide liner 144 that is unreactive to the etch process used to remove the silicon 120. The semiconductor structure 100 therefore includes voids 146 where before the silicon 120 remained in a continuous plane on the back side.

FIG. 6C depicts a cross-sectional side view of the semiconductor structure 100 along a line parallel to line A-A’ in FIG. 1. The semiconductor structure 100 may include passive devices of S/Ds 106 designating an electrical path without a gate 108, but merely connected to the BEOL 134 by S/D contacts 138. The OPL 142 protects both S/Ds 106 of the passive device.

FIG. 6D depicts a cross-sectional side view of a semiconductor structure 200 along an extended line A-A’ in FIG. 1. That is, in certain embodiments the semiconductor structure 200 may use a pattern of OPL 242 to uncover several S/Ds 206, rather than the single S/D 106 in the previous Figures. The pattern of OPL 242 shown in FIG. 6D produces a longer void 246 when the silicon 220 is removed. The illustrated embodiment shows four S/Ds 206 uncovered through the removal of the silicon 220, but fewer (i.e., two or three) of the S/Ds 206, or a greater number (e.g., five, dozens, hundreds) of the S/Ds 206 may be exposed in other locations or other embodiments of the semiconductor structure 200. These S/Ds 206 may be connected to a BEOL 234 (i.e., on the frontside) by S/D contacts 238 (as illustrated) but certain embodiments may include S/Ds 206 that are exposed to the voids 246 and not connected to any S/D contact 238. The etch process used to create the void 246 in FIG. 6D is selective such that BDI 218 is not affected when the silicon 220 is removed. While only a single S/D is shown with the void X46 and the BILD in the Figures below, any of the embodiments disclosed herein may use similar processes to remove silicon in any size of void.

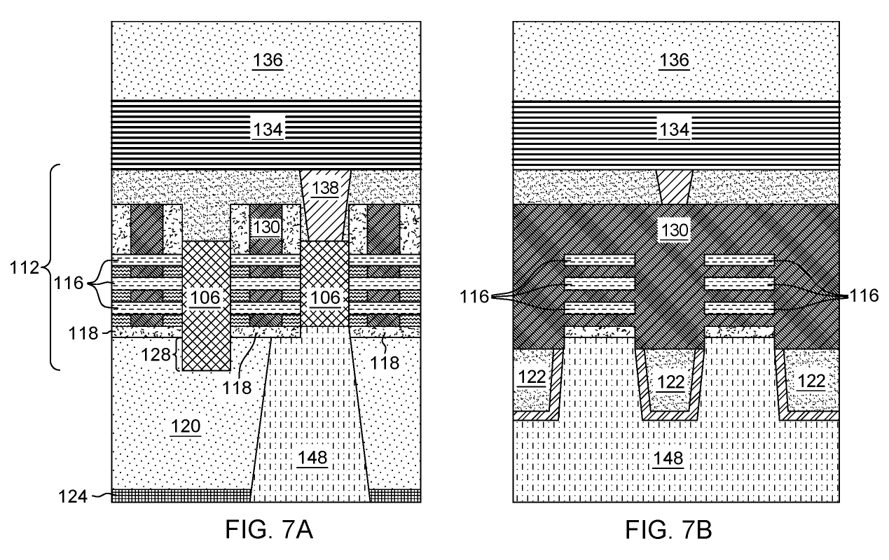

FIGS. 7A and 7B depict cross-sectional side views of the semiconductor structure 100, in accordance with one embodiment of the present invention. FIG. 7A is a cross-sectional view along line A-A’ in FIG. 1, and FIG. 7B is a cross- sectional view along line B-B’ in FIG. 1. The semiconductor structure 100 now includes a backside interlayer dielectric (BILD) 148 filled into the void 146 vacated by the etched silicon 120. The BILD 148 may include materials such as a non-crystalline solid material such as SiN, SiC, SiCN(H), or other silicon compounds for insulating, silicon dioxide (SiO2) undoped silicate glass (USG), tetraethyl orthosilicate (TEOS), low-κ dielectric, or ultra low-κ dielectric materials, fluorosilicate glass (FSG), borophosphosilicate glass (BPSG), a spin-on low-κ dielectric layer, a chemical vapor deposition (CVD) low-κ dielectric layer or any combinations thereof. The material for the BILD 148 may be selected such that the thermal conductivity of the BILD 148 will match well with the copper bonded during the DBC process. The BILD 148 thus prevents defects that could result from the silicon 120 expanding differently than the copper under certain thermal conditions.

The OPL 142 may be ashed and removed. The ashing process may involve subjecting the OPL 142 to high temperatures in the presence of oxygen or other reactive gases. This causes the organic materials to break down and oxidize, leaving behind only the inorganic residues. The exact parameters of the ashing process, such as temperature, duration, and gas environment, can vary depending on the specific materials used in the organic layer and the desired outcome. After ashing, the semiconductor structure 100 can be left with a well-defined planar surface suitable for further processing, such as deposition of additional layers or patterning. Furthermore, the semiconductor structure 100 may be flattened using a chemical-mechanical planarization (CMP) process.

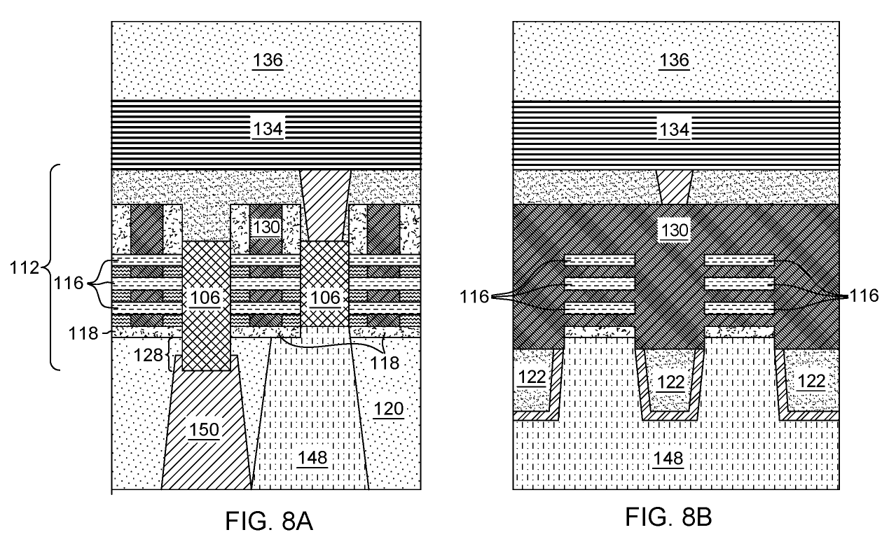

FIGS. 8A and 8B depict cross-sectional side views of the semiconductor structure 100, in accordance with one embodiment of the present invention. FIG. 8A is a cross-sectional view along line A-A’ in FIG. 1, and FIG. 8B is a cross- sectional view along line B-B’ in FIG. 1. The semiconductor structure 100 now includes a backside S/D contact 150 etched and metalized through the silicon 120 to contact the S/D 106. The S/D 106 may be shortened during the etching of the hole for the backside S/D contact 150 such that the protrusion depth 128 is reduced, and the S/D 106 does not protrude passed the BDI 118 quite as far. The S/D 106, even if reduced, will still protrude somewhat passed the BDI 118. The semiconductor structure 100 includes a residual silicon 152 between the backside S/D contact 150 and the BILD 148. The residual silicon 152 is a result of the processes creating the backside S/D contact 150 and the BILD 148. In the cross-sectional view the residual silicon 152 appears as a wedge, but in the three-dimensional actual semiconductor structure 100 the residual silicon 152 will wrap around the backside S/D contact 150 and run along the BILD 148.

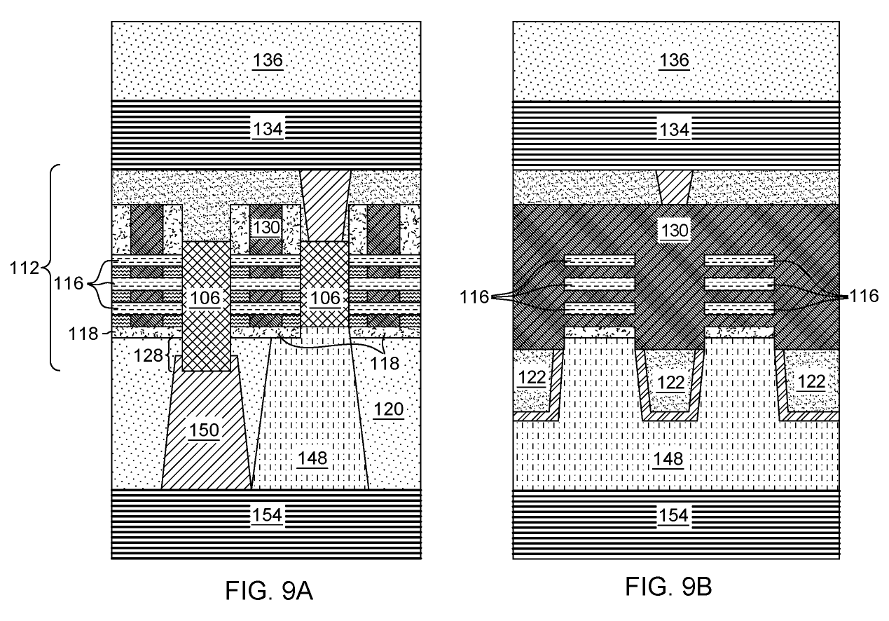

FIGS. 9A and 9B depict cross-sectional side views of the semiconductor structure 100, in accordance with one embodiment of the present invention. FIG. 9A is a cross-sectional view along line A-A’ in FIG. 1, and FIG. 9B is a cross- sectional view along line B-B’ in FIG. 1. The semiconductor structure 100 now includes a backside power deliver network (BSPDN) 154. The BSPDN 154, much like the BEOL 134 includes layers of metal interconnects, power lines, wires, etc. to power the S/Ds 106 in the semiconductor structure 100. The BSPDN 154 is connected to the S/Ds 106 by the backside S/D contacts 150. The BSPDN 154 provides several benefits that enhance performance and efficiency of the semiconductor structure 100. By relocating power delivery interconnects to the backside of the semiconductor structure 100, BSPDN 154 improves power integrity by reducing voltage droop, which ensures a more stable power supply to the S/Ds 106. This stability allows the FETs 110 to operate at higher frequencies with less risk of performance degradation. Additionally, moving power interconnects to the backside frees up space on the frontside for signal routing, which improves power integrity, reduces signal interference, and enhances overall performance. The BSPDN 154 also increases logic density by allowing more efficient use of the frontside of the semiconductor structure 100 for signal interconnects, leading to more compact and efficient chip designs. Additionally, the BSPDN can reduce power loss by minimizing the resistance encountered by power interconnects, resulting in more efficient power distribution and improved energy efficiency.

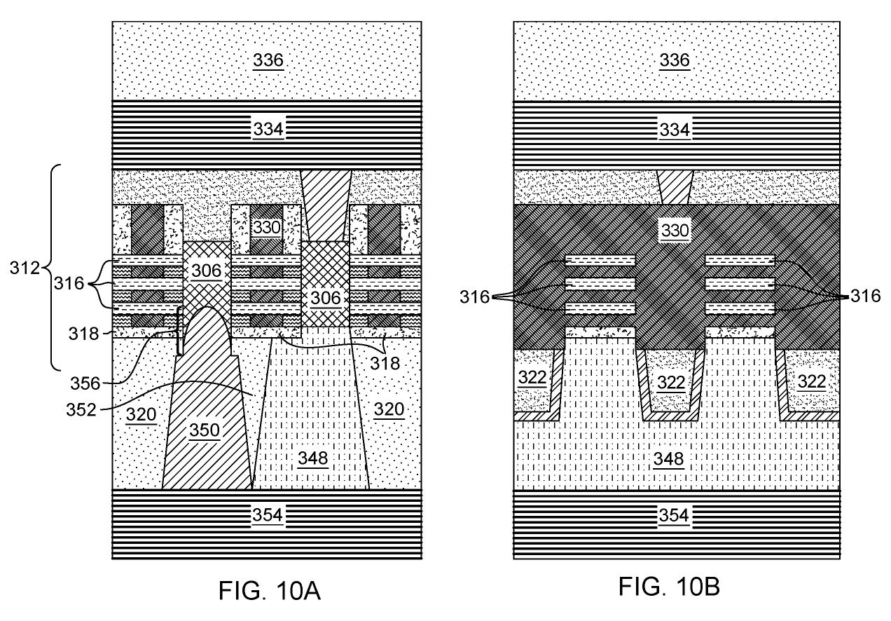

FIGS. 10A and 10B depict cross-sectional side views of a semiconductor structure 300, in accordance with one embodiment of the present invention. FIG. 10A is a cross-sectional view comparable to the view along line A-A’ in FIG. 1, and FIG. 10B is a cross- sectional view comparable to the view along line B-B’ in FIG. 1. Like the embodiment above, the semiconductor structure 300 includes a FEOL 312 with FET devices controlling a signal between S/Ds 306 using a HKMG 330 surrounding nanosheet channels 316. An STI 322 protects the FEOL 312, which may be supported during fabrication by a carrier wafer 336. The S/Ds 306 and the HKMG 330 are connected to a BEOL 334 and/or a BSPDN 354 that control signals and provide power to the FEOL 312. The semiconductor structure 300 may also include a BILD 348 formed similarly to the BILD 148 described above. In contrast to the embodiment of the semiconductor structure 100 above, however, the semiconductor structure 300 forms a backside S/D contact 350 by etching silicon 320 completely down to a BDI 318 formed at the bottom of the nanosheet channels 316. The BDI 318 protects the HKMG 330 from the etch process since the process is selective against etching the BDI 318. The S/Ds 306, however, may be etched during the removal of the silicon 320, and rather than the protrusion (i.e., protruding out the protrusion depth 128) described above, the S/D 306 is recessed such that a portion 356 of the backside S/D contact 350 protrudes into the S/D 306. The additional etching away of the silicon 320 does not, however, result in the total removal of a residual silicon 352, which remains in a space between the BILD 348 and the backside S/D contact 350, as evidence of the process used to fabricate the BILD 348 and the backside S/D contact 350.

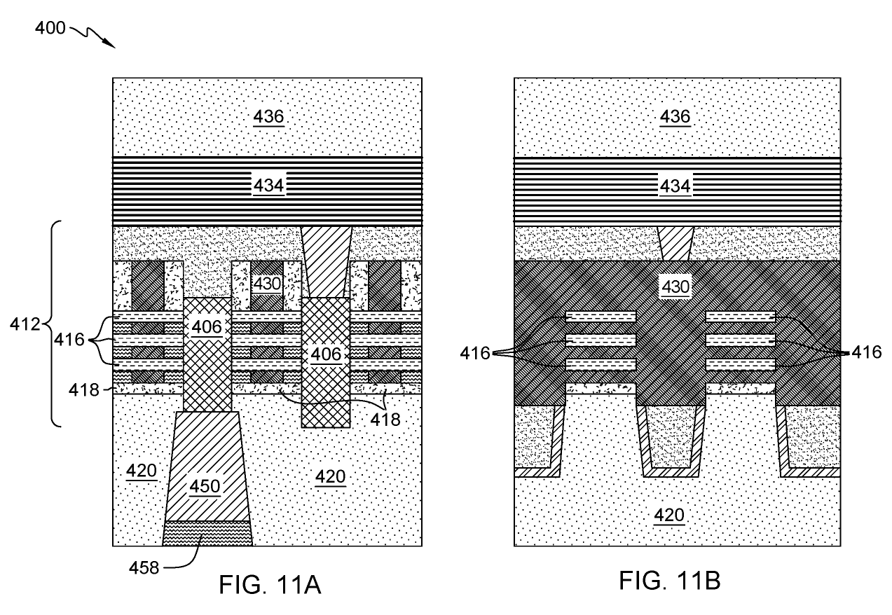

FIGS. 11A and 11B depict cross-sectional side views of a semiconductor structure 400, in accordance with one embodiment of the present invention. FIG. 11A is a cross-sectional view comparable to the view along line A-A’ in FIG. 1, and FIG. 11B is a cross- sectional view comparable to the view along line B-B’ in FIG. 1. Like the embodiments above, the semiconductor structure 400 includes a FEOL 412 with FET devices controlling a signal between S/Ds 406 using a HKMG 430 surrounding nanosheet channels 416. A BDI 418 protects the nanosheet channels 416, which may be supported during fabrication by a carrier wafer 436. The S/Ds 406 and the HKMG 430 are connected to a BEOL 434 and/or a BSPDN 454 that control signals and provide power to the FEOL 412. In contrast to the embodiments of the semiconductor structures 100, 300 above, however, the semiconductor structure 400 has been fabricated with a backside S/D contact 450 in silicon 420 before any BILD. The backside S/D contact 450 includes a contact cap 458 to protect the backside S/D contact 450 during etch processes. After the BILD is fabricated, a residual silicon 452 may be present around the backside S/D contact 450. The S/Ds 406 may be fabricated as protruding into the silicon 420, with the backside S/D contact 450 shortening the protruding depth when etching and metalizing.

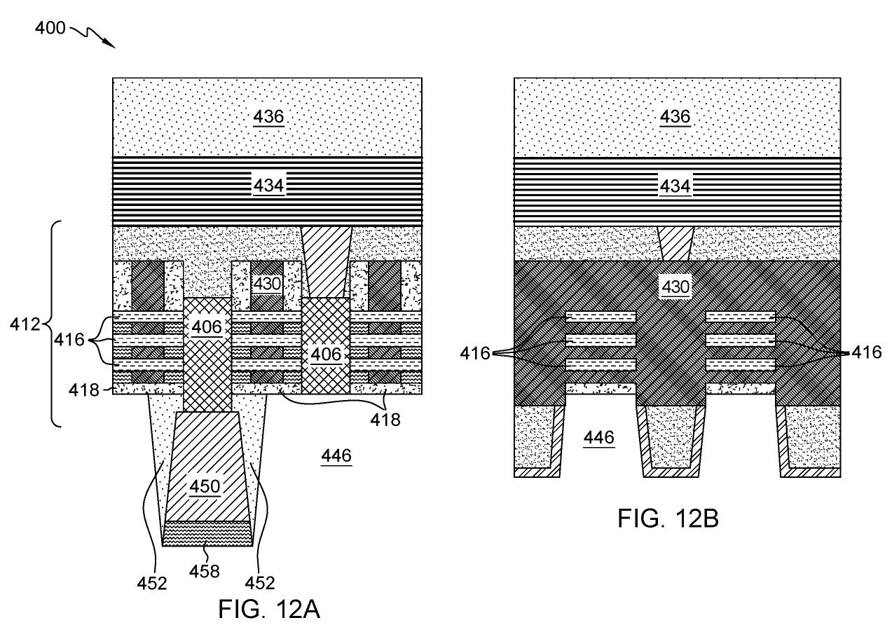

FIGS. 12A and 12B depict cross-sectional side views of the semiconductor structure 400 of FIGS. 11A and 11B, in accordance with one embodiment of the present invention. FIG. 12A is a cross-sectional view comparable to the view along line A-A’ in FIG. 1, and FIG. 12B is a cross- sectional view comparable to the view along line B-B’ in FIG. 1. The semiconductor structure 400 has been etched to remove the silicon 420 and create voids 446. The voids 446 may be etched using a directional etch (e.g., reactive ion etch (RIE)) process with the contact cap 458 providing the masking so that the backside S/D contact 450 is not etched. Other masking materials (not pictured) may also be used to ensure that the voids 446 are etched only in the appropriate locations.

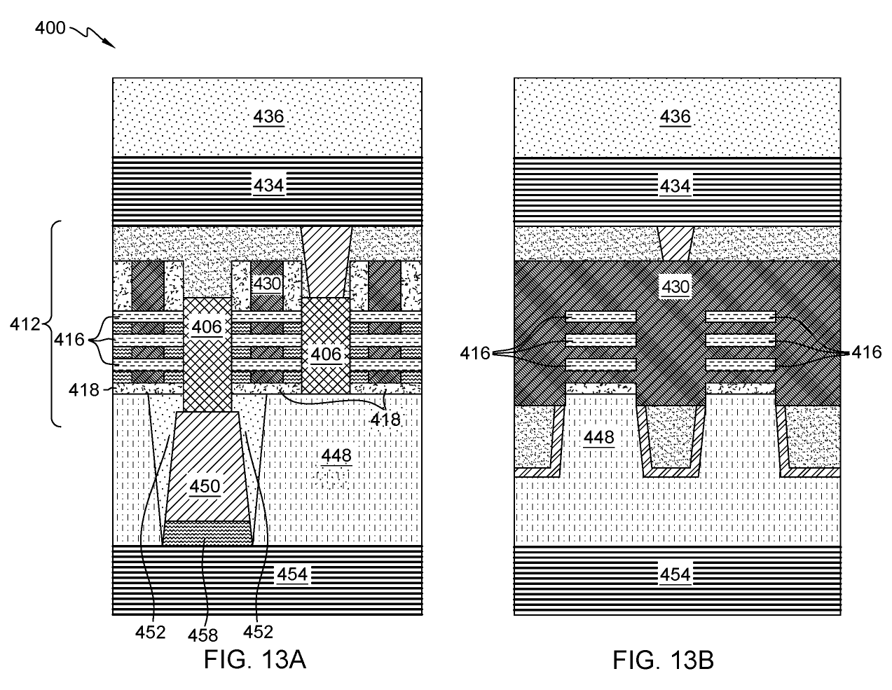

FIGS. 13A and 13B depict cross-sectional side views of the semiconductor structure 400 of FIGS. 11A and 11B, in accordance with one embodiment of the present invention. FIG. 13A is a cross-sectional view comparable to the view along line A-A’ in FIG. 1, and FIG. 13B is a cross- sectional view comparable to the view along line B-B’ in FIG. 1. The semiconductor structure 400 has BILD 448 deposited in the void 446, and a BSPDN 454 fabricated or bonded to the backside of the semiconductor structure 400. The BILD 448 is fabricated from a material that has a thermal coefficient of expansion that matches the BSPDN 454 and the BEOL 434 to minimize defects that can be caused by uneven expansion of the semiconductor structure 400 during operation, including high-temperature operation.

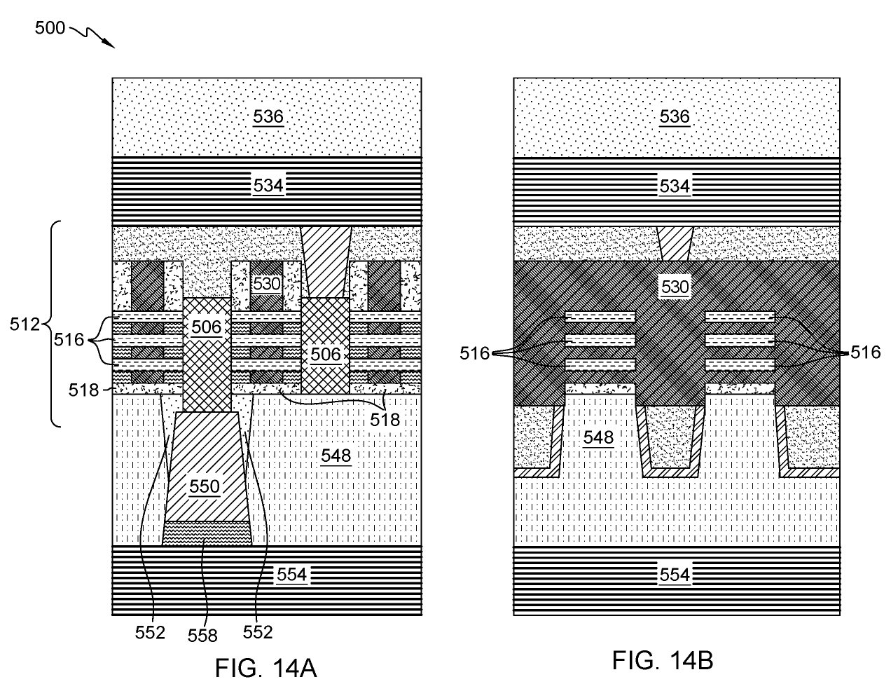

FIGS. 14A and 14B depict cross-sectional side views of a semiconductor structure 500, in accordance with one embodiment of the present invention. FIG. 14A is a cross-sectional view comparable to the view along line A-A’ in FIG. 1, and FIG. 14B is a cross- sectional view comparable to the view along line B-B’ in FIG. 1. Like the embodiments above, the semiconductor structure 500 includes a FEOL 512 with FET devices controlling a signal between S/Ds 506 using a HKMG 530 surrounding nanosheet channels 516. The semiconductor structure 500 may be supported by a carrier wafer 536 during fabrication. The S/Ds 506 and the HKMG 530 are connected to a BEOL 534 and/or a BSPDN 554 that control signals and provide power to the FEOL 512. In addition to the embodiment of the semiconductor structure 400 above, however, the semiconductor structure 500 includes a residual silicon 552 (around a backside S/D contact 550) that has been trimmed. That is, prior to the deposition of the BILD 548, the semiconductor structure 500 is etched with a directional etch while the backside S/D contact 550 is protected by a contact cap 558, and following the directional etch, an isotropic etch process that trims the residual silicon 552 and further reduces the total amount of silicon (e.g., silicon 120 above) that is present in the semiconductor structure 500.

The methods described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first source/drain (S/D) electrically connected to a backside contact on a backside;
a second S/D electrically connected to a frontside contact on a frontside;
a bottom dielectric isolation (BDI) between the first S/D and the second S/D;
a backside interlayer dielectric (BILD) protruding past the BDI into direct contact with the second S/D; and
a residual silicon between the BILD and the backside contact.

2. The semiconductor structure of claim 1, wherein the first S/D protrudes below the BDI.

3. The semiconductor structure of claim 1, wherein the backside contact protruding past the BDI into direct contact with the first S/D.

4. The semiconductor structure of claim 1, further comprising a backside contact cap between the backside contact and a backside interconnect network.

5. The semiconductor structure of claim 4, wherein the residual silicon contacts the backside contact cap.

6. The semiconductor structure of claim 4, wherein the residual silicon contacts the backside contact and does not contact the backside contact cap.

7. The semiconductor structure of claim 1, wherein the BILD protrudes past the BDI into direct contact with a third S/D and a fourth S/D.

8. A method, comprising:
forming a front-end-of-line (FEOL) in silicon comprising a first gate comprising a bottom dielectric isolation (BDI), a first source/drain (S/D) that protrudes below the BDI, and a second S/D that protrudes below the BDI;
etching the silicon and a portion of the second S/D to form a void; and
depositing a backside interlayer dielectric (BILD) that protruding past the BDI into direct contact with the second S/D.

9. The method of claim 8, further comprising forming a backside S/D contact electrically connected to the first S/D.

10. The method of claim 9, further comprising forming a contact cap on the backside S/D contact.

11. The method of claim 8, further comprising trimming a residual silicon after forming the void.

12. The method of claim 8, wherein the void is formed over a plurality of S/Ds additional to the second S/D.

13. A semiconductor structure, comprising:
a first source/drain (S/D) electrically connected to a backside contact on a backside;
a second S/D adjacent to the first S/D;
a backside interlayer dielectric (BILD) on the backside of the second S/D; and
a residual silicon between the BILD and the backside contact.

14. The semiconductor structure of claim 13, further comprising:
a high-κ metal gate (HKMG) between the first S/D and the second S/D; and
a bottom dielectric isolation (BDI) between the HKMG and the BILD.

15. The semiconductor structure of claim 14, wherein the first S/D protrudes below the BDI between the first S/D and the second S/D.

16. The semiconductor structure of claim 13, further comprising a backside contact cap between the backside contact and a backside interconnect network.

17. The semiconductor structure of claim 16, wherein the residual silicon contacts the backside contact cap.

18. The semiconductor structure of claim 16, wherein the residual silicon contacts the backside contact but not the backside contact cap.

19. The semiconductor structure of claim 13, wherein the BILD protrudes past the BDI into direct contact with a third S/D and a fourth S/D.

20. The semiconductor structure of claim 13, wherein the backside contact protrudes past the BDI into direct contact with the first S/D.
